(19) United States
(12) Patent Application Publication
(10) Pub. No.: US 2014/0309517 A1
(43) Pub. Date: Oct. 16, 2014

(54) Method of Automatically Analyzing Brain Fiber Tracts Information

(71) Applicant: National Taiwan University, Taipei (TW)

(72) Inventors: Wen-Yih Tseng, Taipei (TW); Yu-Jen Chen, Taipei (TW); Yu-Chun Lo, Taipei (TW); Yung-Chin Hsu, Taipei (TW)

(73) Assignee: National Taiwan University, Taipei (TW)

(21) Appl. No.: 13/971,473

(22) Filed: Aug. 20, 2013

(30) Foreign Application Priority Data
Apr. 10, 2013 (TW) 102112718

(51) Int. Cl. G01R 33/56; G01R 33/563

(52) U.S. Cl. CPC G01R 33/5608; G01R 33/56341
USPC 600/410

(57) ABSTRACT

The present invention provides a method of automatically analyzing brain fiber tracts information. The method includes the steps as follows: providing a brain reference template with a plurality of reference fiber tracts, wherein the reference fiber tracts have at least a coordinate information; providing an object image with a plurality of object fiber tracts, and each object fiber tract includes at least an object information; transforming the object image according to the brain reference template; sampling the transformed object image with the brain reference template to make the object information co-register with the coordinate information, and further to get an analyzing result of each object information.

### CROSS-REFERENCE TO RELATED APPLICATIONS

This Non-provisional application claims priority under 35 U.S.C. §119(a) on Patent Application No(s). 102112718 filed in Taiwan, Republic of China, Apr. 10, 2013, the entire contents of which are hereby incorporated by reference.

### FIELD OF THE INVENTION

The invention is related to an analyzing method and, more particularly, to a method of automatically analyzing brain fiber tracts information.

### BACKGROUND OF THE INVENTION

Magnetic Resonance Imaging (MRI) technology has been widely used in clinical diagnosis and research, wherein diffusion MRI (dMRI) technology has developed into a main method to explore the white matter nerve tracts. DMRI technology is used to explore the tiny tissues structure by measuring the Brownian motion of water molecules. It can represent the tiny structure of the nervous fiber including the size or the direction of nervous.

In biological tissues, the diffusion motion of water molecules may be obstructed by surroundings substances or the environment affect to lead to that the diffusivity of the water molecules in biological tissues is anisotropic, which means the flow speed of the water molecules are different. For example, the nerve fibers, such as the white matter includes intense anisotropy, it means the diffusion of the water molecules are specific move towards. The neurones, such as gray matter include weak anisotropy, it means single diffusion coefficient cannot be used to represent the diffusion characteristics. By such characteristics, currently there are several dMRI technologies to measure the direction of the neural fiber by measuring a plurality of dMRI images with different diffusion gradient.

Diffusion Tensor Imaging (DTI) technology can be used to describe the diffusion direction of water molecules. Through arithmetic operations, some indicators can be derived to represent anisotropy. Fractional Anisotropy (FA) can be taken as an example, FA is used to determine the degree of diffusion tensor. FA is defined as a proportion relative to the whole diffusion tensor, the value of FA is larger, the diffusion anisotropy is stronger, and it means more directional.

Diffusion the Spectrum Imaging (DSI) technology can measure the diffusion probability distribution of water molecules by using the direction and the intensity of different diffusion gradient. DSI technology is a sampling technology containing six dimensions of information, and the diffusion probability of water molecules can be calculated from the three-dimensional images relative to the three-dimensional Q space. Therefore, through DSI technology for sampling the brain images, the direction of nerve fibers in three-dimensional space can be calculated more complete, and the path of the nerve tracts can be effectively found.

In addition, in the prior art, if it is assumed that the main diffusion direction of water molecules and nerve tracts toward the same direction, the target fibers of DTI or DSI need to be determined before capturing the brain fiber information of the individual, the parameters also need to be set to determine the region of interest (ROI). It needs to take advantage of the experts manually selecting to recognize the ROI. After recognizing the ROI, reconstruction parameters of the brain fiber tracts need to be set on a platform. After reconstructing a number of fiber tracts, it needs enough experienced experts for each fiber trim and screening to pick out reasonable fiber tracts for subsequent processing. It is quite time-consuming, and may cause many problems, such as reconstruction error or reconstructing unreasonable fiber tracts.

### SUMMARY OF THE INVENTION

The invention provides a method of automatically analyzing brain fiber tracts information. It's convenient for the clinic staff to diagnose brain diseases and determine the position of relevant organizations. It can solve the problems that artificially selecting relevant position of MRI images and time consumption. Moreover, the method can be used to accurately find the possibility of early brain lesions.

A first embodiment of the method of automatically analyzing brain fiber tracts information of the invention comprises the steps as follows:

Step 1. providing a brain reference template with a plurality of reference fiber tracts, wherein the reference fiber tracts have at least one coordinate information;

In an embodiment, the brain reference template is generated by using method of Large Deformation Diffeomorphic Metric Mapping (LDDMM) to analyze and transform a plurality of normal brain images. The normal brain images are the images of DSI.

The brain reference template is reconstructed by using method of tractography or transformed by a specific template to generate the reference fiber tracts, wherein the specific template comprises a plurality of brain fiber tracts. In an embodiment, the reference fiber tracts can be atlas, which is not limited herein.

The reference fiber tracts are co-registered to make the reference fiber tracts have the at least a coordinate information.

Step 2. An object image with a plurality of object fiber tracts is provided, and each object fiber tract includes at least an object information. In an embodiment, the object fiber tract also can be atlas, which is not limited herein.

Since the nerve fibers have orientation in three-dimension space, an orientation distribution function can be taken to show the information. In an embodiment, Generalized Fractional Anisotropy (GFA) can be taken to show all the object information of each object fiber tract, which is not limited herein.

Step 3a. The object image is transformed according to the brain reference template to generate a transformed object image. In an embodiment, the object image is generated by using LDDMM to make brain reference template be proceeded a transformation process.

Step 4a. The transformed object image is sampled with the brain reference template to make the object information co-register with the coordinate information, and further to get an analyzing result of each object information.

A second embodiment of the method of automatically analyzing brain fiber tracts information of the invention comprises the steps as follows:

Step 1. A brain reference template with a plurality of reference fiber tracts is provided. The reference fiber tracts have at least one coordinate information. The detail of the Step 1 in the second embodiment is same as the Step 1 in the first embodiment, and is not descripted more than what is needed again.

Step 2. An object image with a plurality of object fiber tracts is provided, and each object fiber tract includes at least an object information. The detail of the Step 2 in the second embodiment is same as the Step 2 in the first embodiment, and is not descripted more than what is needed again.

Step 3b. The object image is transformed according to the brain reference template. The most detail of the Step 3b in the second embodiment is same as the Step 3a in the first embodiment, the only difference is that the object image is transformed according to the brain reference template to generate a transformed transformation matrix.

Step 4b. The transformed transformation matrix is used to inverse transform the reference fiber tracts and further to generate a plurality of inverse-transformed reference fiber tracts. Wherein the inverse-transformed reference fiber tracts include at least one second coordinate information, and the object information is respectively corresponding to the second coordinate information, and further to get an analyzing result of each object information.

The method of automatically analyzing brain fiber tracts information is provided in the invention. In the method, first, a brain reference template is provided for further obtaining all the important information of the object image. Then the analyzing result of the object information is automatically analyzed. It can effectively improve the problems that the method of the prior art needs enough experienced experts for each fiber trim and time consumption of screening There will be no the problems of reconstruction error or reconstructing unreasonable fiber tracts.

The white matter fiber tracts (atlas) is taken as the object information in the invention, the analyzed GFA information not only can represent the integrity of the whole brain fiber tracts, but also can represent the connection relationship of the white matter and the gray matter after combining the three-dimensional coordinate information. It is able to show the true complex neural structures in the brain, which can provide usage to clinical disease on and neuroscience research.

The advantages and spirit of the present invention, and further embodiments can be further understood with the following embodiments and appended figures.

### BRIEF DESCRIPTION OF THE DRAWINGS

FIG. 1 is a flow chart showing a first embodiment of the method of automatically analyzing brain fiber tracts information in the invention;

FIG. 2 is a diagram of the Step 1;

FIG. 3 is a diagram showing the step 3a and step 4a of the first embodiment in the invention;

FIG. 4 is a flow chart showing a second embodiment of the method of automatically analyzing brain fiber tracts information in the invention; and

FIG. 5 is a diagram showing the step 3b and step 4b of the second embodiment in the invention.

### DETAILED DESCRIPTION OF THE INVENTION

For clarity of disclosure, and not by way of limitation, the detailed description of the invention is divided into the subsections that follow.

To further illustrate the present invention, the following specific examples are provided.

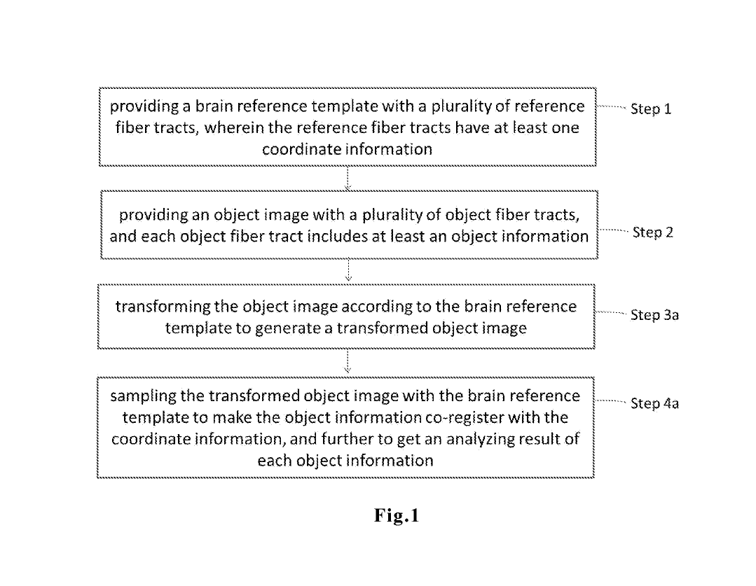

FIG. 1 is a flow chart showing a first embodiment of the method of automatically analyzing brain fiber tracts information in the invention. The method of the first embodiment includes the steps as follows:

Step 1. A brain reference template with a plurality of reference fiber tracts is provided. The reference fiber tracts have at least one coordinate information.

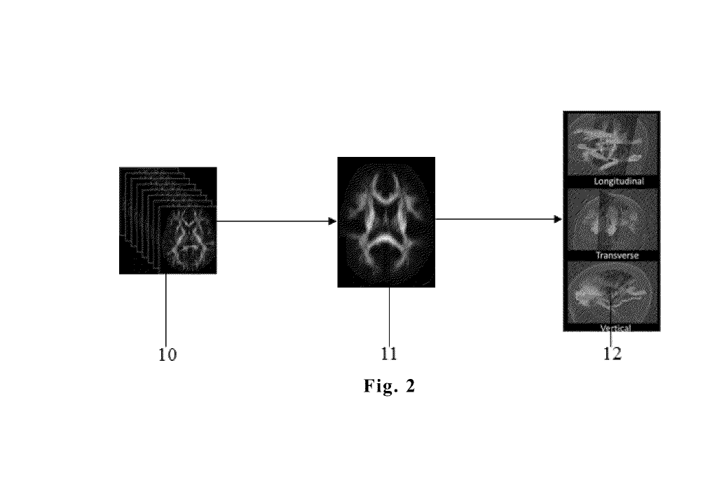

In an embodiment, FIG. 2 is a diagram of the Step 1, the brain reference template 11 is generated by using method of LDDMM to analyze and transform a plurality of normal brain images 10. The normal brain images 10 are the images of DSI or DTI, which is not limited herein.

The method of LDDMM is used to simulate the transformation process between the two images as the flow of a liquid, and define a difference function between the two images, and further to derive the shortest path between two images. As a result, it can be proceeded a linear analysis for a nonlinear anatomical images with highly variation in the same coordinate space.

LDDMM is a transformation method for a structure data, the image may deform during transformation process, but the structure information of the transformed data is still remained. For example, a transformed brain image still remains the information of original brain fiber tracts.

Because LDDMM includes the feature, in a preferred embodiment, the present invention generates the brain reference template 11 by using method of LDDMM, which is not limited herein. From the medical point of view, although the sizes of the different individuals of the normal homology are different, the shapes of them are similar. They have the same data structure, through LDDMM to transform, the deformed image still can remain internal connection, and the adjacent relationship of tracts is also remained. It's suitable for determination afterwards.

In another embodiment, the brain reference template 11 can be also generated by transforming and co-registering the grey matter signal of the normal brain images or the white matter signal of the normal brain images, which is not limited herein.

Besides, although the brain reference template 11 is generated by transforming and co-registering the normal brain images, if other normal brain images can be collected afterwards, the brain reference template 11 can be synchronously updated, which is not limited herein.

The brain reference template 11 is reconstructed by using method of tractography or transformed by a specific template to generate the reference fiber tracts 12, wherein the specific template comprises a plurality of brain fiber tracts. In an embodiment, the reference fiber tracts 12 can be atlas, which is not limited herein. In an embodiment, please refer to FIG. 2, the brain reference template 11 is reconstructed by using method of tractography, which is not limited herein.

The reference fiber tracts 12 are co-registered to make the reference fiber tracts 12 have the at least a coordinate information. The signals of the brain reference template 11 can be intensified by accumulate the plurality of normal brain images 10. Therefore, each reference fiber tracts 12 can be clearly shown, and can be respectively given coordinate information according to its location. A reference fiber tracts 12 can include a plurality of coordinate information, which is not limited herein.

Nerve fibers are distributed in three-dimension space, as a result, three-dimension coordinate can be taken as the coordinate information, such as (X₁, Y₁, Z₁), which is not limited herein.

Step 2. An object image 20 with a plurality of object fiber tracts is provided, and each object fiber tract includes at least an object information. Because the signal of single image is weak, its information structure cannot be clearly shown. That is to say, the signal of the object fiber tract is weak, so the object image 20 cannot clearly show every complete object fiber tract. In an embodiment, the object fiber tract can be atlas, which is not limited herein.

Since the nerve fibers have orientation in three-dimension space, an orientation distribution function can be taken to show the information. In an embodiment, GFA can be taken to show all the object information of each object fiber tract. GFA can represent the anisotropism of the fiber tracts, the larger the value of GFA is, the more intensive the anisotropism of distribution is, and it represents the fiber tracts are more anisotropic. If it is represented by feature vector, the object information of the invention also can be FA, which is not limited herein.

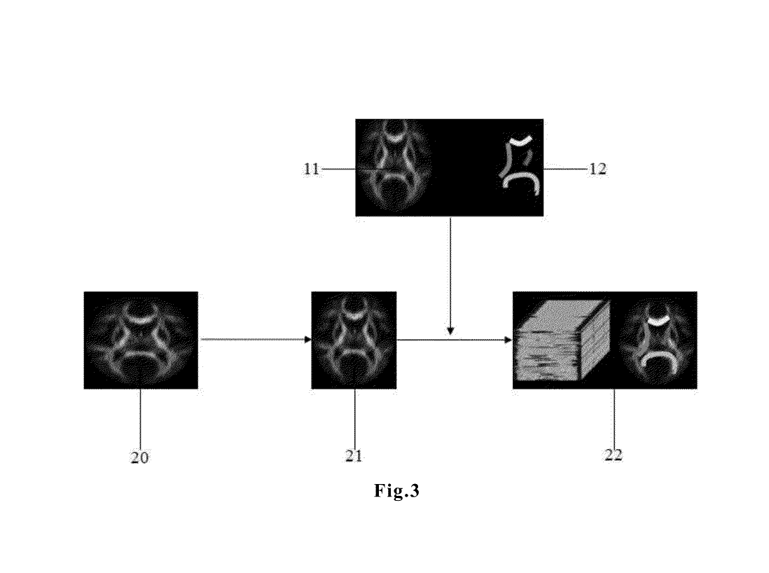

Step 3a. The object image 20 is transformed according to the brain reference template 11 to generate a transformed object image 21. In an embodiment, FIG. 3 is a diagram showing the step 3a and step 4a of the first embodiment in the invention. The object image 20 is generated by using LDDMM to make brain reference template 11 be proceeded a transformation process. That is to say, after transforming, only the contour and the main structure of the object image 20 are according to the brain reference template 11, the inside detail structure information of the object image 20 are still remained, so the adjacent relationship of tracts is also remained.

In another embodiment, the transformation process uses a method of grey matter signal of the object image 20 corresponding to grey matter signal of the brain reference template 11, or white matter signal of the object image 20 corresponding to white matter signal of the brain reference template 11, which is not limited herein.

Step 4a. The transformed object image 21 is sampled with the brain reference template 11 to make the object information co-register with the coordinate information, and further to get an analyzing result 22 of each object information.

As mentioned above, please refer to FIG. 3, the object image 20 cannot clearly show every complete object fiber tract. However, after transforming, the contour of the transformed object image 21 can be according to the brain reference template 11, and each reference fiber tracts 12 of the brain reference template 11 not only can be clearly shown, but also be respectively given coordinate information according to its location. As a result, the object image 20 can co-register with the coordinate information, to get the analyzing result of each object information.

In an embodiment, the transformed object image 21 is sampled with the brain reference template 11 by making the object fiber tracts corresponding to reference fiber tracts 12, which is not limited herein.

In an embodiment, the analyzing result can be the combination of the GFA of the object information and its corresponding coordinate information, or the combination of the FA and its corresponding coordinate information, which is not limited herein.

In an embodiment, the analyzing result 22 of the invention can be analyzed and calculated to provide signals for determination afterwards. For example, the analyzing result 22 is analyzed and calculated to generate a connectome information. The connectome information is the connection signals of neuron with each other. When intensity of existing synapses or connection relationship changes, the ability to transfer information will be changed, this message can provide physicians for further examination of the patient.

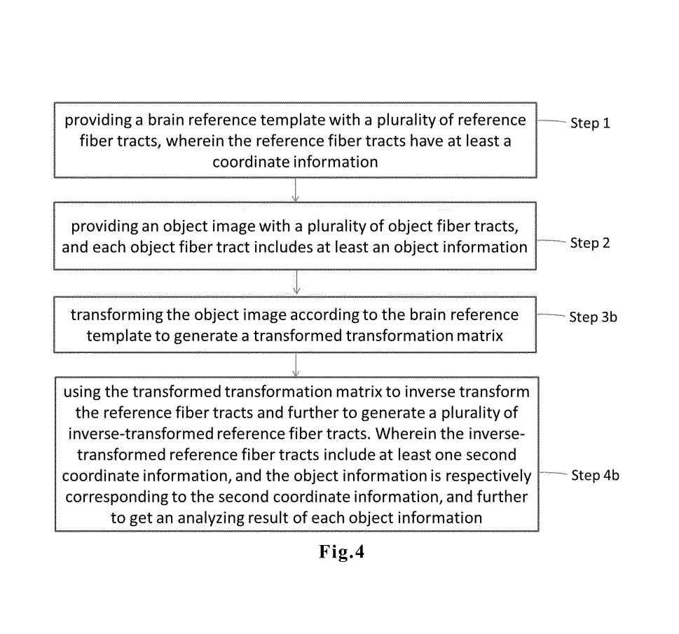

FIG. 4 is a flow chart showing a second embodiment of the method of automatically analyzing brain fiber tracts information in the invention. The method of the second embodiment includes the steps as follows:

Step 1. A brain reference template with a plurality of reference fiber tracts is provided. The reference fiber tracts have at least one coordinate information. The detail of the Step 1 in the second embodiment is same as the Step 1 in the first embodiment, and is not descripted more than what is needed again.

Step 2. An object image 20 with a plurality of object fiber tracts is provided, and each object fiber tract includes at least an object information. The detail of the Step 2 in the second embodiment is same as the Step 2 in the first embodiment, and is not descripted more than what is needed again.

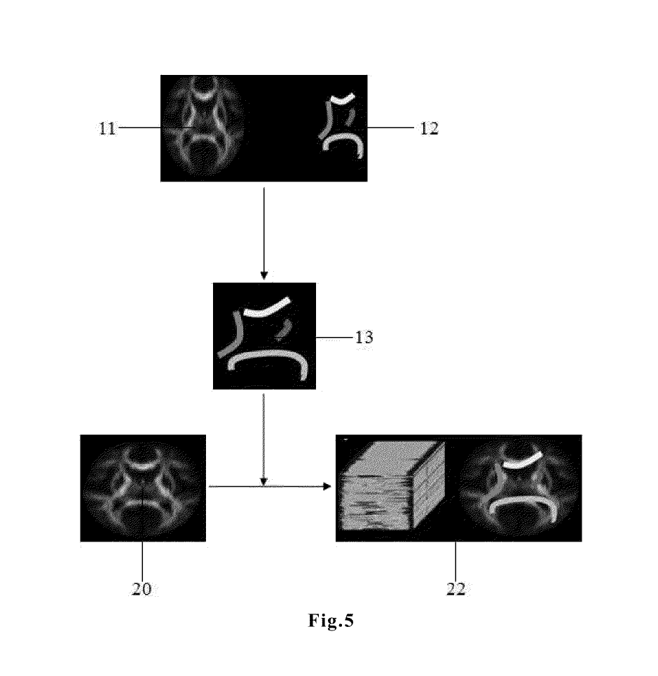

Step 3b. The object image 20 is transformed according to the brain reference template 11. The most detail of the Step 3b in the second embodiment is same as the Step 3a in the first embodiment, the only difference is that the object image 20 is transformed according to the brain reference template 11 to generate a transformed transformation matrix. FIG. 5 is a diagram showing the step 3b and step 4b of the second embodiment in the invention.

Step 4b. The transformed transformation matrix is used to inverse transform the reference fiber tracts 12 and further to generate a plurality of inverse-transformed reference fiber tracts 13. Wherein the inverse-transformed reference fiber tracts 13 include at least one second coordinate information, and the object information is respectively corresponding to the second coordinate information, and further to get an analyzing result 22 of each object information.

The difference between the first embodiment and the second embodiment is that in the first embodiment, the object information is co-registered with the coordinate information to get the analyzing result 22 of each object information, and in the second embodiment, the original coordinate information of the reference fiber tracts 12 is used to inverse transform according to the transformed transformation matrix of Step 3b, and further to generate a new coordinate information. The object information is respectively corresponding to the new coordinate information (second coordinate information), and further to get the analyzing result 22 of each object information.

In an embodiment, the inverse-transformed reference fiber tracts 13 are respectively corresponding to the object fiber tracts, and further to make the object information co-register with the second coordinate information, which is not limited herein.

In an embodiment, the analyzing result 22 can be the combination of the GFA of the object information and its corresponding coordinate information, or the combination of the FA and its corresponding coordinate information, which is not limited herein.

In an embodiment, the analyzing result 22 of the invention can be analyzed and calculated to provide signals for determination afterwards. For example, the analyzing result 22 is analyzed and calculated to generate a connectome information. The connectome information is the connection signals of neuron with each other. When intensity of existing synapses or connection relationship changes, the ability to transfer information will be changed, this message can provide physicians for further examination of the patient.

The method of automatically analyzing brain fiber tracts information is provided in the invention. In the method, first, a brain reference template 11 is provided for further obtaining all the important information of the object image. Then the analyzing result of the object information 22 is automatically analyzed. It can effectively improve the problems that the method of the prior art needs enough experienced experts for each fiber trim and time consumption of screening There will be no the problems of reconstruction error or reconstructing unreasonable fiber tracts.

The white matter fiber tracts (atlas) is taken as the object information in the invention, the analyzed GFA information not only can represent the integrity of the whole brain fiber tracts, but also can represent the connection relationship of the white matter and the gray matter after combining the three-dimensional coordinate information. It is able to show the true complex neural structures in the brain, which can provide usage to clinical disease on and neuroscience research.

Although the present invention has been described in terms of specific exemplary embodiments and examples, it will be appreciated that the embodiments disclosed herein are for illustrative purposes only and various modifications and alterations might be made by those skilled in the art without departing from the spirit and scope of the invention as set forth in the following claims.

What is claimed is:

1. A method of automatically analyzing brain fiber tracts information, the steps of the method comprising:
Step 1. providing a brain reference template with a plurality of reference fiber tracts, wherein the reference fiber tracts have at least one coordinate information;
Step 2. providing an object image with a plurality of object fiber tracts, and each object fiber tract includes at least an object information;
Step 3. transforming the object image according to the brain reference template to generate a transformed object image; and
Step 4. sampling the transformed object image with the brain reference template to make the object information co-register with the coordinate information, and further to get an analyzing result of each object information.

2. The method according to claim 1, wherein the brain reference template is generated by using method of Large Deformation Diffeomorphic Metric Mapping (LDDMM) to analyze and transform a plurality of normal brain images.

3. The method according to claim 2, wherein the normal brain images are the images of Diffusion Spectrum Imaging (DSI) or Diffusion Tensor Imaging (DTI).

4. The method according to claim 1, wherein the brain reference template is reconstructed by using method of tractography or transformed by a specific template to generate the reference fiber tracts, wherein the specific template comprises a plurality of brain fiber tracts.

5. The method according to claim 1, wherein the reference fiber tracts are co-registered to make the reference fiber tracts have the at least a coordinate information.

6. The method according to claim 1, wherein the object information is information of Generalized Fractional Anisotropy (GFA) or Fractional Anisotropy (FA).

7. The method according to claim 6, wherein the analyzing result is a combination of the GFA of the object information and its corresponding coordinate information.

8. The method according to claim 2, wherein the object image is generated by using LDDMM to make brain reference template be proceeded a transformation process.

9. The method according to claim 8, wherein the transformation process uses a method of grey matter signal of the object image corresponding to grey matter signal of the brain reference template, or white matter signal of the object image corresponding to white matter signal of the brain reference template.

10. The method according to claim 1, wherein the method of sampling the transformed object image with the brain reference template is making the object fiber tracts corresponding to reference fiber tracts.

11. The method according to claim 1, further comprise a step to analyze the analyzing result to generate a connectome information.

12. A method of automatically analyzing brain fiber tracts information, the steps of the method comprising:
Step 1. providing a brain reference template with a plurality of reference fiber tracts, wherein the reference fiber tracts have at least a coordinate information;
Step 2. providing an object image with a plurality of object fiber tracts, and each object fiber tract includes at least an object information;
Step 3. transforming the object image according to the brain reference template to generate a transformed transformation matrix; and
Step 4. using the transformed transformation matrix to inverse transform the reference fiber tracts and further to generate a plurality of inverse-transformed reference fiber tracts. Wherein the inverse-transformed reference fiber tracts include at least one second coordinate information, and the object information is respectively corresponding to the second coordinate information, and further to get an analyzing result of each object information.

13. The method according to claim 12, wherein the brain reference template is generated by using method of LDDMM to analyze and transform a plurality of normal brain images.

14. The method according to claim 13, wherein the normal brain images are the images of DSI or DTI.

15. The method according to claim 12, wherein the brain reference template is reconstructed by using method of tractography or transformed by a specific template to generate the reference fiber tracts, wherein the specific template comprises a plurality of brain fiber tracts.

16. The method according to claim 12, wherein the reference fiber tracts are co-registered to make the reference fiber tracts have the at least a coordinate information.

17. The method according to claim 12, wherein the object information is information of GFA or FA.

18. The method according to claim 17, wherein the analyzing result is a combination of the GFA of the object information and its corresponding coordinate information.

19. The method according to claim 13, wherein the object image is generated by using LDDMM to make brain reference template be proceeded a transformation process.

20. The method according to claim 12, wherein the method of sampling the transformed object image with the brain reference template is making the object fiber tracts corresponding to reference fiber tracts.

21. The method according to claim 12, wherein the inverse-transformed reference fiber tracts are respectively corresponding to the object fiber tracts to make the object information respectively corresponding to the second coordinate information.

22. The method according to claim 12, further comprise a step to analyze the analyzing result to generate a connectome information.
